(19) United States
(12) Patent Application Publication
(10) Pub. No.: US 2009/0061088 A1
(43) Pub. Date: Mar. 5, 2009

(54) METHOD AND DEVICE FOR PRODUCING AND PROCESSING LAYERS OF SUBSTRATES UNDER A DEFINED PROCESSING ATMOSPHERE

(75) Inventors: Hubertus Von Der Waydbrink, Dresden (DE); Michael Hentschel, Dresden (DE); Marco Kenne, Schwarzheide (DE); Andrej Wolf, Dresden (DE)

Correspondence Address: HESLIN ROTHENBERG FARLEY & MESITI PC, 5 COLUMBIA CIRCLE, ALBANY, NY, 12203, US

(73) Assignee: VON ARDENNE Anlagentechnik GmbH, Dresden (DE)

(21) Appl. No.: 12/176,454

(22) Filed: Jul. 21, 2008

(30) Foreign Application Priority Data
Sep. 4, 2007 (DE) 10 2007 041 729.4

(51) Int. Cl. C23C 16/00; C23C 16/458; H05B 6/00

(52) U.S. Cl. 427/255.5; 118/729; 118/722; 392/416

(57) ABSTRACT

A method is provided for producing a processing atmosphere for coating substrates, with this method primarily being used in CVD-processes for precipitating an individual layer or a system of individual layers under defined processing atmospheres, in which processing gas is supplied to a coating chamber in a defined manner and exhausted. Via the method and related devices, a variable processing atmosphere is adjustable inside the coating chamber in a flexible, reliable and homogenous manner, and requiring a reduced maintenance and energy expense, even when the substrate is heated. The processing gas is created by at least one gas channel extending perpendicular in reference to the substrate by way of supplying gas flow or exhausting, with a lateral extension being equivalent to the width of the substrate.

### CROSS REFERENCE TO RELATED APPLICATIONS

This application claims priority of German application No. 10 2007 041 729.4 filed on Sep. 4, 2007, the entire disclosure of which is hereby incorporated herein by reference

### BACKGROUND ART

The invention relates to a method for producing a processing atmosphere for producing and processing layers on substrates, with processing gas being supplied to a processing chamber and exhausted in a defined manner. The invention also relates to devices for executing the method.

This method is predominantly applied in CVD-processes (chemical vapor deposition) for precipitating an individual layer or a system of individual layers under defined processing atmospheres in such pressure ranges that allow the creation of gas flows. Here, the processing atmospheres for the production of the individual layers may deviate from each other.

For the purpose of coating, substrates are moved passing in a substrate level one or more coating sources in a coating chamber or in a sequence thereof. Both the production as well as the processing of layers occurs either continuously or discontinuously depending on the applicable coating method and depending on the embodiment of the coating arrangement. This principle processing sequence is the same for appropriate embodiments of the coating source and/or the coating source environment even for the processing of layers already precipitated on a substrate, for example a modification of the layer composition or the layer features. For this reason the following descriptions related to coatings shall also relate to the processing of existing layers. This method can also be used in a particular embodiment for PVD-processes (physical vapor deposition).

It is known from various application fields to produce or to process both individual layers as well as layered systems on substrates, with the latter comprising several layers positioned over top of each other, which in turn have been precipitated under different precipitation conditions and/or using different coating materials, e.g., thin-layer solar cells or optic systems of functional layers. In any case it is necessary for the precipitation of the individual layers to separately produce the processing atmospheres necessary in the coating chamber, if applicable deviating from each other. A deviation of the processing atmospheres can relate to various parameters, e.g., the material to be precipitated, the pressure, or the composition of the processing gas. Further, for the creation of homogenous and low-defect individual layers it is essential for each processing atmosphere to keep the pressure and the composition of the atmosphere perpendicular in reference to the direction of transportation, i.e., homogenously over the width of the substrate.

For this purpose, in known coating arrangements, such as described in DE 10 2004 014 323 A1, particularly for the coating of large substrates with long coating sources, seen in the direction perpendicular in reference to the direction of transportation, gas supply systems are used by which processing gas is supplied in the environment of the coating source distributed over the width of the substrate. In U.S. Pat. No. 5,096,562 it is also described to feed inert and reactive gas over the entire length of the tubular cathode as the coating source in order to homogenously operate the cathode. Here, any gas supplied or exhausted for the execution of the respective coating method in a coating chamber shall be included, e.g., an inert carrier gas such as argon, or a reactive gas, such as oxygen or nitrogen, for a reactive coating and also additional gaseous additives or a mixture of these components.

Furthermore, it is necessary to keep the substrate and the processing atmosphere free from contamination, clusters of coating material, and condensate, because such contaminations considerably influence the quality of the layers.

In the following, such a connected volume of a coating arrangement shall be considered a coating chamber which is not separated by tightly sealing valves but is provided with separating or dividing walls having openings for transporting the substrate through the coating chamber. Using such separating walls, which protrude at one side or at both sides of the substrate almost to the substrate in the coating chamber, the coating chamber can be divided into at least two compartments following each other in the direction of transportation. A coating compartment comprises one or more coating sources. For producing a defined processing atmosphere the coating compartment can be evacuated either directly via a connection of a vacuum pump provided in the chamber wall of the compartment or indirectly via an exhaust opening in the dividing wall using an adjacent pumping compartment. The operating gas can be inserted into the coating compartment via a gas inlet.

The number and the sequence of the different compartments within the coating chamber differ according to the layer or the layer systems to be produced. In complex layer systems, with their individual layers having to be applied with distinctly varying layer parameters and coating atmospheres, the entire separation of the various coating atmospheres occurs by way of gas separation, conditional for ensuring the features of the layer to the extent possible.

For this purpose, the transportation room in a pumping compartment, in which the substrate is moved through the arrangement, is separated from the exhaust room by separating walls arranged in the close proximity of the substrate and approximately parallel in reference to the substrate. This way a tunnel-shaped chamber is formed in the area of the substrate, the pumping channel, which based on its cross-section as well as the low and particularly the comparable gas pressure of the compartments, adjacent to the pumping channel at both sides, represents a flow resistance. A maximum passive gas separation can be ensured between these two adjacent compartments by appropriately designing the flow resistance. Such installations in a coating chamber require a lot of space and maintenance expense, particularly in complex coating systems, and are always exposed sites for undesired precipitations as well as sources of contaminations.

The problem of undesired precipitations and the partially resulting increased maintenance expense is increased when the coating method is executed at high temperatures, at which perhaps even the substrate is heated by a separate heating element.

Based on the high temperatures in the coating chamber, coating material or condensate introduced when the arrangement is opened collects, particularly at installations that are not heated themselves or that are mechanically and thermally connected to unheated or cooled components, e.g., the chamber wall of the coating chamber, which must be removed in a time consuming and energy intensive manner.

Therefore the object of the invention is to provide a method and a device for executing the method by which a variable processing atmosphere can be adjusted within a coating chamber of a coating arrangement in a flexible, reliable, and homogenous manner, using a reduced maintenance and energy expense, namely using the heated substrate as well.

### BRIEF SUMMARY OF INVENTION

In the method according to the invention a defined atmosphere of processing gas is produced for coating a substrate inside a coating chamber by creating a flow which is aligned alternatively away from the substrate or aligned towards the substrate. Such a flow can act like a gas curtain or a gas meter in the coating chamber, depending on the flow speeds and the pressure conditions. It can be adjusted very limitedly within the coating chamber with conditions deviating from the environmental atmosphere of the processing gas and thus serve various functions.

In order to realize such particular functions, as a gas curtain or a gas meter or local eddies one embodiment of the method provides for exhausting the processing gas or inserting the processing gas through the gas channel or both in addition to the common gas inlets and gas outlets which are regularly realized by sockets or similarly suitable inlets and outlets in the chamber wall.

Based on the lateral extension of one or more flows over the width of the substrate, the homogeneity of the layer precipitation is not influenced or even improved over the width of the substrate. In one embodiment both flows, i.e., one running towards the substrate created by feeding processing gas and one aligned away from the substrate by way of suction, can be created even jointly in one coating chamber. Such a combination is also possible in the same compartment, of course if the coating chamber is divided into compartments by way of separating walls. This combination of supply and exhaustion in one volume can be used, e.g., to produce a particularly homogenous atmosphere of processing gas.

In the following, for a better overview and thus not described in greater detail, the claimed process is described for a coating chamber without any division into compartments. The method can however be used just as well for an individual compartment or several ones within a coating chamber.

The described flows of processing gas are created with the help of at least one gas channel, which is located above the side of the substrate over which a coating source is located as well. It extends over the width of the substrate and is provided with one or more openings in that extension. This gas channel is designed such that it can be optionally used both for the supply as well as for exhaustion.

In the present description the terms “above the substrate” and “upstream the coating source” are not to be understood in reference to an external system, but merely as a distanced position in reference to the substrate and/or in reference to the coating source. Thus, “above” relates both to above as well as underneath the substrate in reference to the vertical extension of the coating chamber. Therefore, the methods include coatings of substrates according to the following description, both at the top as well as the bottom and also two-sided ones. Similarly, “upstream” can represent both upstream as well as downstream the coating source. The direction of reference is here the direction of transportation of the substrate.

For the arrangement of one or more gas channels extending laterally in the coating chamber for supplying processing gas and/or exhausting processing gas closely connected to the motion and processing of the substrate performed in the chamber, of course, very different designs, arrangements, and combinations are possible depending on the motion and the processing of the substrate. Therefore, both exhausting as well as simultaneously supplying are possible in different gas channels upstream and downstream in reference to the coating source or a graduated arrangement at one or both sides of the coating source. Furthermore, a supplementary arrangement at the side of the substrate where no coating source is arranged is possible as well.

A gas channel is heated in an embodiment of the method for exhausting the processing gas and the device for performing the method. This way each surface of the exhaustion device in the coating chamber, which is cold due to the thermal connection of a gas channel to a frequently cooled chamber wall, and thus the attachment of coating material at these cold surfaces is reduced. In addition to the reduction of loss of coating material the reliability of the exhaust device is also improved and its maintenance expense is reduced, by which the energy expense is reduced for regular operation. The reduction of the precipitating coating material is of particular importance for high-rate coating methods, because the precipitating layers particularly deposit at cold surfaces.

Due to the fact that the gas channel of the processing gas supplied and thus the processing gas supplied itself can be heated it impinges the substrate at a temperature which may range approximately to that of the temperature of the substrate. This way, the precipitation of the layer and its features can be positively influenced.

In a particular embodiment of the gas channel, embodied as a heating element, in order to avoid disturbing precipitations cold surfaces are geometrically arranged such that the flow conditions are preferably not influenced in the exhaust device. For this purpose, for example cross-sections of pipelines are expanded at a location where temperatures occur below the condensation point. This creates a geometric space as large as possible, which prevents constriction in the cross-section of the flow if precipitation of the exiting coating material occurs. Such an expansion can occur in an area, e.g., in which the gas channel passes through the chamber wall and thus is in a thermal contact therewith. The determination of the relevant temperature ranges of the gas channel is to be determined by way of simulation, e.g., when knowing the temperature at which the coating process is performed, and the temperature and materials of adjacent parts.

Another advantageous embodiment of the method of the invention combines the heating of the substrate with the heating of the exhaust device by the substrate and the exhaust device being heated jointly by one or more surface heaters. This way the temperatures of the gas channels and the supplied processing gas are well approximated to the substrate temperature and simultaneously the necessary space and energy requirements are optimized.

In addition to an arrangement of a laterally extended supply of processing gas and exhaustion of processing gas the openings of the gas channel themselves are also to be designed very differently in order to yield various effects. While the openings for exhausting the processing gas should regularly be of such size that no damaging pressure drop occurs, i.e., that the performance of the vacuum pump is not reduced by a cross-section of the opening or openings being too small the flow speed then can be adjusted via the size of the opening or openings for the supply of processing gas or via the flow rate of the processing gas passing. In this case, not every pressure drop is to be considered a damaging pressure drop, because it always occurs both via the openings as well as the length of the gas channel. Rather a pressure drop is to be considered damaging when the intended special function of the flow is no longer ensured. A damaging pressure drop is to be avoided, e.g., by the diameter of the channel being large in reference to the diameter of the openings.

Depending on the pressure ratios in the coating chamber and the flow rate, various functions can be realized with the flow of the processing gas. For example, the flow of a gas curtain created adjacent to the coating source or an aperture slot in the chamber wall can be varied up to a so-called gas meter by which based on very high flow speeds the atmospheres can be influenced in a targeted manner at a defined location, e.g., in the proximity of the substrate, or contaminants or loose condensate can be removed from the substrate or kept at a distance therefrom.

Due to the fact that the gas channel can be used both for supplying processing gas as well as exhausting processing gas, adjustable openings are advantageous in the gas channel. The function of the gas channel, regardless if it is used for supplying processing gas or exhausting processing gas, is created such that a gas supply source or an exhaust device is connected to this gas channel at the side of the atmosphere.

Additionally or alternatively, in another embodiment of the device the gas channel is rotational around its longitudinal axis to adjust the lateral flow of the supplied processing gas. This way it is possible to create a flow with a variable angle in reference to the substrate level and to locally differentiate the described effects.

The creation of a laterally extended flow of the processing gas by way of its exhaustion and/or supply via the width of the substrate and the locally differentiated exhaustion also allows the coating under, for example, two processing gas atmospheres, deviating from each other with regard to their pressures, inside the same coating chamber. For this purpose, the coating chamber is divided into two coating compartments, in this case with a dividing wall, which is provided in the substrate level with a gap-shaped penetrating opening to transport the substrate through the chamber. Both coating compartments are each provided with at least one coating source and one of the above-described devices for supplying processing gas and exhausting processing gas using one or more gas channels. This way, the above-described possibilities for adjusting the processing atmosphere can be adjusted separately for each compartment.

The exhaustion is realized in both compartments over the width of the substrate and thus over the width of the penetrating openings of the chamber wall and perhaps supplemented by a gas curtain in the proximity of the penetrating opening, so that a pressure compensation between the two compartments does not occur caused by the targeted flow of the processing gas in the proximity of the slot. For the coating, based on the cooperation of the gap-shaped penetrating opening in the dividing wall and the targeted flow of the processing gas, extending parallel in reference to the penetrating opening, the embodiment of a tunnel-shaped flow resistance, extending parallel in reference to the substrate over an extended distance, as known from prior art, is unnecessary so that the device according to the invention provides considerable space savings in this case.

In order to separate the gas of adjacent compartments the described measures for producing an atmosphere of processing gas and the gas channels and heating elements used for this purpose can also be combined with the known methods for gas separation. For example, for separating gas frequently a compartment is inserted between two coating compartments, into which only inert gas is inserted, e.g., distributed over the width of the substrate. This way, via the described gas channels for exhausting processing gas, the gas coming from the intermediate chamber is exhausted in the adjacent coating compartments and an overflow of processing gas from one of the coating chambers to the next one and vice versa is prevented or at least considerably reduced.

### BRIEF DESCRIPTION OF THE DRAWING FIGURES

In the following the invention shall be explained in greater detail using an exemplary embodiment. The corresponding drawing shows in

FIG. 1 a spatial section of a coating chamber in a cross-sectional illustration parallel in reference to the direction of transportation,

FIG. 2 a spatial section of a coating chamber in a cross-sectional illustration perpendicular in reference to the direction of transportation,

FIG. 3 a cross-section of a heating element with a gas channel for supplying gas, and

FIG. 4 an enlarged illustration of a section of a gas channel with a condensation chamber in a cross-sectional illustration.

### DETAILED DESCRIPTION

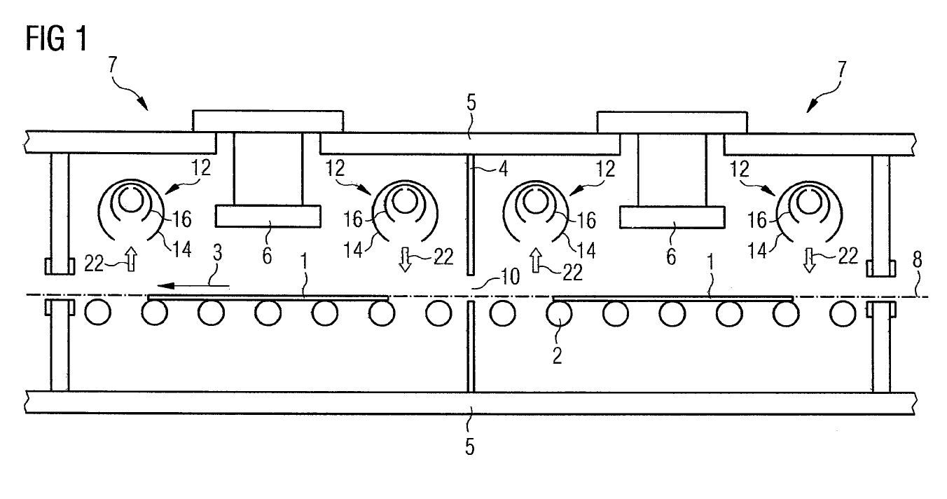

FIG. 1 shows a section of an inner chamber of a coating chamber, through which a substrate 1 for coating is transported via a multitude of transportation rollers 2 and other suitable transportation elements of a transport system. In the following, the method shall be described using a vacuum coating, however, it is also applicable to coating methods occurring under atmospheric pressures, such as thermal gas phase reactions in so-called diffusion furnaces.

The coating chamber is divided into two coating compartments 7 via a dividing wall 4, which abuts the upper and the lower chamber wall 5 of the coating chamber or alternatively a horizontal separating wall. Both coating compartments 7 are each provided with a coating source 6, for example a gas phase reactor.

Due to its size and thermal load in the exemplary embodiment the dividing wall 4 is made from a carbon fiber-compound material, however, it may also comprise stainless steel, ceramics, or another material inert in reference to the processing media. In the substrate level 8 the dividing wall 4 is provided with a slot-shaped penetrating opening 10. The penetrating opening 10 is selected of such size that the dividing wall 4 approaches the substrate 1 close enough in the circumferential direction that the vaporous coating materials are largely separated from each other and ensures an unhindered transportation of the substrate 1.

Two heating elements 12 are arranged each at both sides of the dividing wall 4 and thus adjacent to the respective coating source 6 as well as at both sides of the coating source 6. Each heating element 12 serves, in addition to other heating devices not shown, to heat the substrate or at least to maintain a previously adjusted substrate temperature and is arranged perpendicular in reference to the direction of transportation 3 of the substrate 1 and thus approximately parallel in reference to the coating source 6, which extends over the entire width of the substrate (perpendicular in reference to the drawing level).

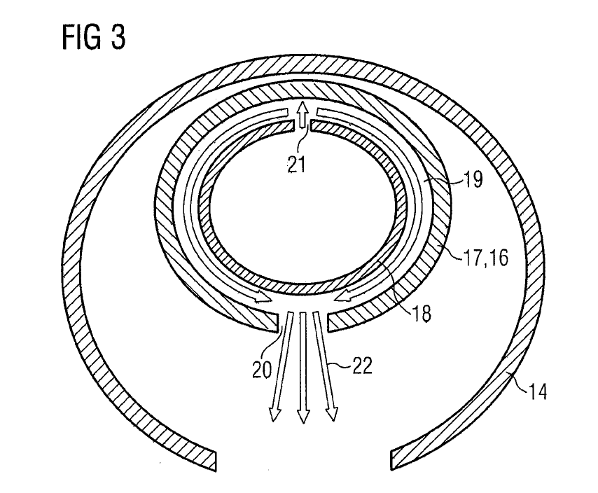

A heating element 12 is shown in detail in FIG. 3, in a cross-sectional representation. It comprises a heat-radiating source 14, which may provide an arbitrary suitable embodiment in order to heat the substrate via heat radiation. In the exemplary embodiment shown it is represented by the jacket surface of a cylinder, which surrounds a gas channel 16 arranged inside thereof. The heat radiation source 14 is mounted to the gas channel 16 via a suitable fastener (not shown). Based on this arrangement of the gas channel 18 in reference to the heat radiation source 14 the heat radiation source 14 simultaneously heats the substrate 1 and the gas channel 16.

In the exemplary embodiment shown, the gas channel 16 is of a tubular shape and comprises an external tube 17 and an internal tube 18 arranged concentric in reference thereto, however it may also show a different cross-section or another shape suitable for the purposes described above. The gas to be supplied flows through the internal tube 18 and exits through one or more openings 21 into an annular gap 19, located between the external tube 17 and the internal tube 18, and therefrom through one or more openings 20 in the external tube out of the gas channel 16. The annular gap 19 is adjusted to an even thickness, e.g., via spacers (not shown). The openings 21, 22 in the internal and the external tube are offset in reference to each other such that the gas has to travel a distance in the annular gap 19 as long as possible. Due to the fact that the external tube 17 is almost entirely surrounded by the cylindrical heat radiation source 14, the gas flowing in the annular gap 19 is to be heated to the necessary temperature. In the cylindrical heat radiation source 14 a section of the jacket surface, located opposite the opening in the external tube, i.e., the opening in the gas channel 20, is cut such that gas exiting the gas channel can be aligned unhindered to the substrate.

By designing the geometry of the tubular diameter and the openings in the tubes the gas flow can be adjusted to the potential functions described above. In order to regulate the gas flow the size of at least the openings 20 in the external tube can be adjusted. Various shapes are suitable as openings. Either a multitude of small openings, arranged on a jacket line of the tube, or one or more slot-shaped openings are located on the jacket line of the gas channel for a lateral gas flow, i.e., extending over the width of the substrate, according to FIG. 3 of the external tube.

When in another embodiment of the heat radiation source the heating of the gas is ensured in a different manner or the flow to be adjusted requires it and also when the gas channel 16 is used for exhausting the gas, the gas channel 16 can alternatively comprise a simple, one-layer hollow body. When the gas channel 16 is used for exhausting gas, the direction of flow, shown in FIG. 3 by arrows, is to be reversed appropriately.

According to FIG. 1, gas channels 16 according to FIG. 3 are components both of a device for supplying as well as a device for exhausting the processing gas of the coating process. The other components of both devices, not shown in greater detail, by which the processing gas is supplied to or exhausted from the coating chamber, follow the gas channel 16. In both coating compartments 7, one of the gas channels 16 shown serves to supply processing gas and the second one to exhaust processing gas.

As already shown, such an arrangement is only one of the numerous potential combinations of gas channels and heating elements. Additionally, it is possible that one gas channel is installed at one or both sides of the coating source for the supply and one gas channel for the exhaustion of processing gas. This way it is possible to create eddy-like gas flow adjacent to the coating source. In another embodiment, e.g., left and right from the coating source, one gas channel and one exhausting channel can be installed.

Each gas channel 16 extends over the entire width of the substrate 1, together with the heat radiation source 14, and is provided at least in the area in which it is located opposite the substrate 1, with one or more of the openings 20, described in FIG. 3, and used for the supplying processing gas and exhausting processing gas such that a flow of processing gas develops which extends perpendicular in reference to the substrate 1 and over its entire width.

For the coating process, the substrate 1 is first moved via transportation rollers 2 in the direction of transportation 3 underneath a first heating element 12 and heated there. A gas flow 22 is aligned towards the substrate from the gas channel 16 in the first heating element 12, by which the processing gas is supplied. The substrate is continuously moved further through the coating chamber. Underneath the first coating source 6 the coating occurs with the first coating material, using a first pressure p₁ of the processing gas. By another movement of the substrate 1, said substrate 1 passes the second heating element 12 of this coating compartment and thus the exhaust of the processing gas, which is realized by the second gas channel 18 arranged in the heat radiation source 14.

Subsequently the substrate 1 passes the slot-shaped penetrating opening 10 of the dividing wall 4 and thereafter the second coating compartment 7 having two additional heating element 12 and a second coating source 6 arranged between the heating elements 12 for another material precipitation. The coating of the substrate 1 with the second layer occurs at a second pressure p₂ of the processing gas, which is different from the first pressure p₁. In the second coating compartment 7 a gas flow 22 is also created via the two gas channels 18 connected to the heating elements 12 at both sides of the coating element 6, each extending over the entire width of the substrate 1, flowing towards and away from the substrate 1. The aligned gas flows 22 of the processing gases in both coating compartments 7 in the proximity of the dividing wall 4 largely prevent any gas exchange through the penetrating openings 10 of the dividing wall 4. Such a division of the coating chamber into coating compartments 7 with different processing atmospheres may also comprise more than two coating compartments 7.

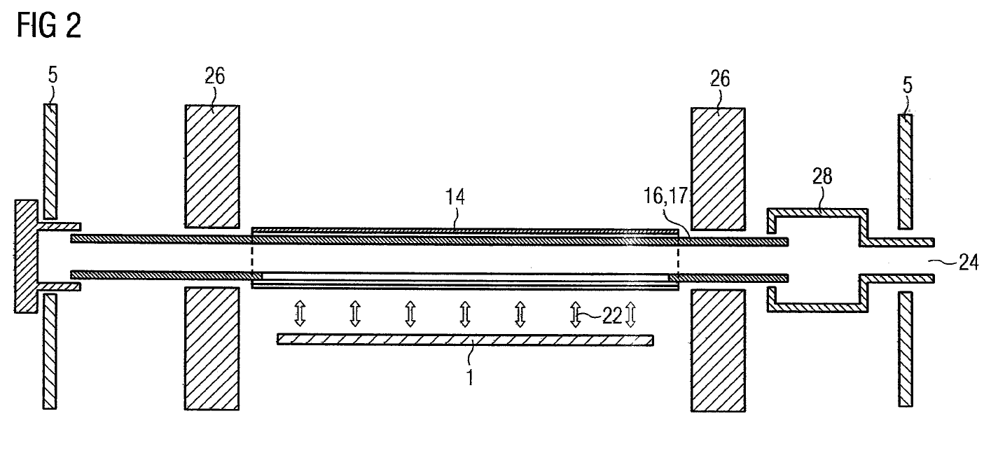

FIG. 2 shows a heating element 12 with a gas channel 16 inside the coating compartment perpendicular in reference to the direction of transportation of the substrate. The gas channel 16, which extends inside the heat radiation source 14, is extended beyond the heat radiation source 14 in order to realize an assembly of the device at the lateral chamber walls 5 of the coating chamber as well as to implement the power and voltage supply and a connection 24 to a vacuum pump or alternatively to a gas supply for supplying the processing gas via this chamber wall 5. In this case, the gas channel 16 comprises a heat conducting material so that even in this area, outside the heat radiation source 14, it is warm enough to prevent precipitations of the coating material. At its second end, located opposite the connection 24, the gas channel 16 is closed.

In order to maintain defined thermal conditions in the coating area and to protect the area of the chamber wall 5 with penetrations, supply units, or drives arranged thereat, heat protection devices 26, usually heat insulating walls, are arranged at both sides of the substrate between the substrate and the chamber wall 5. Depending on the temperature to be adjusted for the coating and the embodiment of the chamber wall 5 as well as their above-described components the heat protection devices 26 may also be omitted alternatively.

In order to perhaps precipitate transported remnants of coating material in a targeted fashion, in a particular embodiment, cold surfaces are geometrically arranged to avoid disturbing precipitations such that the flow conditions in the gas channel particularly in the exhausting device are not influenced. For this purpose, cross-sections of pipelines are expanded for example at a position where temperatures occur below the condensation point. This creates a geometric space as large as possible, which in case of precipitations of exiting coating material prevents any constriction in the conduit to develop.

According to FIG. 2, for this purpose the gas channel 16 is provided with a condensation chamber 28 in its progression between a heat protection device 26 and the chamber wall 5 and thus the unheated and cooler section of the coating compartment, which based on its lower temperature of the jacket surface of the gas channel acts as a condensation trap. It is formed by an expanded cross-section of the gas channel 16 so that precipitations of condensed coating material influence the gas flow to a negligible extent.

Furthermore, the condensation chamber 28 is embodied separable from the gas channel 16 (shown schematically by a slot between the two of them). This results in a better thermal separation of the heated part of the gas channel 16 inside the heat radiation source 14 and thus an improved function as a condensate trap. Furthermore, the condensation chamber 28 requires less maintenance and expense for the removal of condensate.

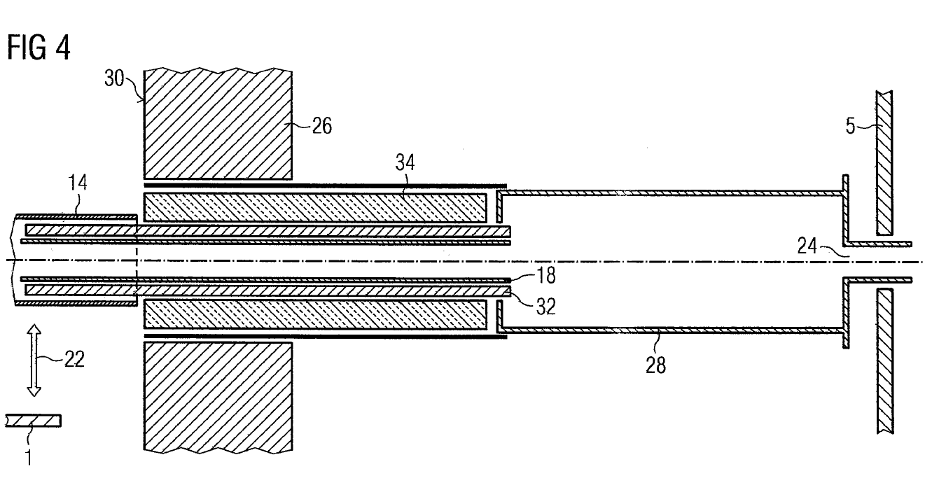

An embodiment of the section of the gas channel 16 serving as a condensation chamber 28 is shown in FIG. 4 in an enlarged illustration. This embodiment serves such a thermal separation between the warm section of the gas channel 16, in which no condensation shall occur, and the condensation chamber, with its temperature to be kept below the condensation temperature of the coating material.

For this purpose, in the area from the internal surface and outside the heat protection device a highly heat-conducting socket 32 is pushed onto the warm internal tube 18 of the gas channel 16, which extends to the heat radiation source 14 and is thus heated thereby. The entire internal tube 18 is maintained at a temperature above the condensation point by this socket 32. Alternatively, this can also occur by a separate heater, which is to be designed such that it fails to influence the function of the condensation chamber 28 adjacent thereto.

The condensation chamber 28 is thermally uncoupled from the internal tube 18 and the socket 32 of the separate heater and is located outside the heat protection device 26. In order to support the thermal uncoupling the socket 32 or the alternative separate heater is covered by heat insulation 34. In case such measures fail to ensure the temperature of the wall of the condensation chamber 28, it is possible to achieve this via a thermal coupling to a cooling chamber wall 5 or an active cooling.

Of course, the penetrations of the gas channel 16 or a flange through the chamber wall 5, shown in the schematic representations of 2 and 5 in dot-dash lines, are embodied in a completely tight fashion. The selected representation only serves to illustrate the individual components of the coating device.

1. A method for producing a processing atmosphere for producing and processing layers on a substrate, in which in a coating chamber processing gas is supplied and exhausted in a defined manner, wherein a gas flow is created by exhausting processing gas in the coating chamber at least at a side of the substrate at which a coating source is arranged, via a gas channel extending perpendicular in reference to a direction of transportation of the substrate through the coating chamber, said gas flow being aligned away from the substrate and being provided with a lateral extension in a width of the substrate as well as perpendicular in reference to the direction of transportation.

2. A method according to claim 1, wherein a supply of processing gas occurs via a gas channel perpendicular in reference to the direction of transportation and distributed over the width of the substrate.

3. A method according to claim 1, wherein at least one gas channel is heated via a heating element.

4. A method for producing a processing atmosphere for the creation and processing of layers on a substrate, in which a processing gas is supplied to a coating chamber and exhausted in a defined manner, wherein at least at a side of the substrate at which a coating source is arranged, a gas flow is created by a supply of processing gas via a gas channel extending perpendicular in reference to a direction of transportation of the substrate and provided with at least one opening, said gas flow being aligned towards the substrate and having a lateral extension in a width of the substrate as well perpendicular in reference to the direction of transportation and the gas channel as well as the processing gas to be supplied are heated via a heating element.

5. A method according to claim 4, wherein exhaustion of processing gas and/or supply of processing gas via the gas channel occurs in addition to an outlet of processing gas and/or an inlet of processing gas into a chamber wall of the coating chamber.

6. A method according to claim 5, wherein, at least at the side of the substrate at which a coating source is arranged, the processing gas, distributed over the width of the substrate, is exhausted via an other gas channel extending perpendicular in reference to the direction of transportation of the substrate and the other gas channel being also heated by a heating element.

7. A method according to claim 4, wherein simultaneously the substrate is heated via said heating element.

8. A method according to claim 1, wherein at both sides of the coating source one gas flow each is created having said lateral extension.

9. A method according to claim 1, wherein an additional gas flow occurs at a side of the substrate where no coating source is arranged.

10. A method according claim 4, wherein during the supply of processing gas via the gas channel a gas flow with a defined flow rate is created by adjusting size of the opening in the gas channel.

11. A method for creating and processing layers on substrates, with processing gas being supplied in a defined manner to a coating chamber and exhausted and a substrate is moved passing a coating source to be coated in a substrate level, wherein a processing atmosphere is produced by the supply of processing gas and/or exhausting processing gas according to claim 2.

12. A method according to claim 11, wherein the substrate is moved passing two coating sources, spatially separated from each other, through a dividing wall having a penetrating opening in the level in which the substrate is moved through the coating chamber, and, for each coating source, adjacent to the dividing wall, at least one gas flow is created with a lateral extension.

13. A coating chamber for producing and processing layers on a substrate via coating methods, through which, in a substrate level, a substrate is moved, having a coating source and a device for supplying and a device for exhausting processing gas from the coating chamber and having a gas channel which extends perpendicular in reference to a direction of transportation of the substrate over the width of the substrate and at least one opening, so that a gas flow is created between the substrate and the gas channel and distributed over the width of the substrate, wherein the gas channel optionally can be connected to the device for supplying processing gas and the device for exhausting processing gas.

14. A coating chamber according to claim 13, wherein a gas channel is arranged for supplying processing gas and a gas channel is arranged for exhausting the processing gas.

15. A coating chamber according to claim 13, wherein flow rate of supplied processing gas is adjustable via size of the opening of the gas channel.

16. A coating chamber according to claim 13, wherein direction of the gas flow of the supplied processing gas can be adjusted by a rotation of the gas channel around a longitudinal axis of the gas channel.

17. A coating chamber according to claim 13, wherein a heating element is allocated to the gas channel for heating the gas channel and for heating processing gas exiting the gas channel.

18. A coating chamber according to claim 13, wherein an additional gas channel is arranged for optionally supplying or exhausting processing gas at a side of the substrate level where no coating source is located.

19. A coating chamber according to claim 13, wherein at least one gas channel is located in a section which is colder during operation of the coating chamber than an other gas channel and is provided with an expansion of its interior diameter.

20. A heating element in a coating chamber having a heat radiating source mounted at a longitudinal fastener, wherein the fastener is embodied as a gas channel having a hollow body, provided with at least one opening for gas penetration and which optionally can be connected to a processing gas source or a vacuum pump.

21. A heating element according to claim 20, wherein size of the opening or number of openings can be adjusted.

22. A heating element according to claim 20, wherein the hollow body is provided with a slot-shaped opening which extends along its longitudinal extension over a defined width.

23. A heating element according to claim 20, wherein the hollow body is provided with several jet-like openings distributed along its longitudinal extension over a defined width.

24. A heating element according to claim 20, wherein the hollow body is provided at least at one end with a detachable assembly socket for mounting a heating element at a chamber wall of a coating chamber and the assembly socket and the hollow body are thermally decoupled.

25. A heating element according to claim 20, wherein the hollow body is provided with an expansion of its interior diameter at a section and that the expanded section of the hollow body is not directly heated by the heat radiating source.

26. A heating element according to claim 20, wherein the hollow body can be rotated.
